(19) United States
(12) Patent Application Publication
(10) Pub. No.: US 2020/0362449 A1
(43) Pub. Date: Nov. 19, 2020

(54) MASK PLATE, METHOD FOR FABRICATING THE SAME AND EVAPORATION DEVICE

(71) Applicants: BOE Technology Group Co., Ltd., Beijing (CN); Chengdu BOE Optoelectronics Technology Co., Ltd., Chengdu (CN)

(72) Inventors: Wenchang ZHANG, Beijing (CN); Chao MA, Beijing (CN); Fujiang JIN, Beijing (CN); Wenbin YANG, Beijing (CN); Wangming ZENG, Beijing (CN); Yongmao WANG, Beijing (CN); Shihua HUANG, Beijing (CN)

(21) Appl. No.: 16/313,207

(22) PCT Filed: Mar. 30, 2018
(86) PCT No.: PCT/CN2018/081216

§ 371 Date: Dec. 26, 2018

(30) Foreign Application Priority Data
Jun. 30, 2017 (CN) 201710525273.1

(51) Int. Cl. C23C 14/04; C23C 14/24

(52) U.S. Cl. CPC C23C 14/042; C23C 14/24

(57) ABSTRACT

A mask plate, a method for fabricating the mask plate, and an evaporation device are disclosed. The mask plate comprises a mask frame and a mask strip. The mask frame comprises a transition layer on a first surface of the mask frame, and the mask strip is welded to the mask frame through the transition layer. In particular, a material of the transition layer is the same as that of the mask strip.

### CROSS REFERENCE TO RELATED APPLICATIONS

The present application is a 35 U.S.C. 371 national stage application of PCT

International Application No. PCT/CN2018/081216, filed on Mar. 30, 2018, which claims the benefit of Chinese Patent Application No. 201710525273.1, filed on Jun. 30, 2017, the entire disclosures of which are incorporated herein by reference.

### TECHNICAL FIELD

The present disclosure relates to the field of semiconductor technologies, and in particular to a mask plate, a method for fabricating the same, and an evaporation device.

### BACKGROUND

In the related art, a mask strip of a mask plate is usually welded to a mask frame by welding. However, the material and crystalline structures of the mask strip are different from the mask frame, so that the welding is relatively difficult and the effect of welding is not good. At the same time, since the mask plate is usually used in a harsh environment of high vacuum, high temperature etc., and the mask plate is exposed to various organic substances, acids, alkalis and the like during use, welding flaws greatly affect the service life of the mask plate.

### SUMMARY

In view of the above, in an aspect of the present disclosure, it is provided a mask plate comprising: a mask frame comprising a transition layer on a first surface of the mask frame; and a mask strip, wherein the mask strip is welded to the mask frame through the transition layer, and a material of the transition layer is the same as that of the mask strip.

According to some embodiments of the present disclosure, a crystalline structure of the transition layer is the same as that of the mask strip.

According to some embodiments of the present disclosure, a material of the mask strip is one of electroformed nickel, electroformed cobalt, and electroformed nickel iron, or a combination thereof.

According to some embodiments of the present disclosure, the material of the transition layer is one of electroformed nickel, electroformed cobalt, and electroformed nickel iron, or a combination thereof.

According to some embodiments of the present disclosure, the mask frame is an Invar piece.

According to some embodiments of the present disclosure, the transition layer is arranged across the first surface.

According to some embodiments of the present disclosure, the transition layer is arranged on a portion of the first surface where the first surface is in contact with the mask strip.

According to some embodiments of the present disclosure, the transition layer is electroformed on the first surface.

According to some embodiments of the present disclosure, the mask strip is welded to the mask frame by laser welding.

In another aspect of the present disclosure, it is provided a method for fabricating a mask plate. The mask plate comprises a mask frame and a mask strip. The method for fabricating the mask plate comprises the steps of: forming a transition layer on a first surface of the mask frame, the material of the transition layer being the same as that of the mask strip; and welding the mask strip to the mask frame through the transition layer.

According to some embodiments of the present disclosure, a crystalline structure of the transition layer is the same as that of the mask strip.

According to some embodiments of the present disclosure, the mask strip is made of one of nickel, cobalt, and nickel iron, or a combination thereof, by electroforming.

According to some embodiments of the present disclosure, the transition layer is made of one of nickel, cobalt, and nickel iron, or a combination thereof, by electroforming.

According to some embodiments of the present disclosure, the mask frame is made of an Invar piece.

According to some embodiments of the present disclosure, the step of forming a transition layer on the first surface of the mask frame comprises forming the transition layer across the first surface.

According to some embodiments of the present disclosure, the step of forming a transition layer on the first surface of the mask frame comprises forming the transition layer on a portion of the first surface where the first surface is in contact with the mask strip.

According to some embodiments of the present disclosure, the step of forming a transition layer on the first surface of the mask frame comprises forming a transition layer on the first surface of the mask frame by electroforming.

According to some embodiments of the present disclosure, the step of welding the mask strip to the mask frame through the transition layer comprises: welding the mask strip to the mask frame through the transition layer by laser welding.

In a further aspect of the present disclosure, it is provided an evaporation device using any of the above-described mask plates.

The additional aspects and advantages of the present disclosure will be partly given in the following description, and part of which will become apparent from the following description or be understood by the practice of this disclosure.

### BRIEF DESCRIPTION OF THE DRAWINGS

The above or additional aspects and advantages of the present disclosure will become apparent and readily understood from the description of the embodiments in conjunction with the following drawings, in which:

FIG. 1 is a schematic view of a mask plate according to an embodiment of the present disclosure; and

FIG. 2 is a flow chart of a method for fabricating a mask plate according to an embodiment of the present disclosure.

### DETAILED DESCRIPTION OF EMBODIMENTS

The embodiments of the present disclosure are described in detail below, and the examples of the embodiments are showed in the accompanying drawings, wherein the same or similar reference numerals indicate the same or similar elements or elements having the same or similar functions throughout the specification. The embodiments described below with reference to the accompanying drawings are exemplary, used only to explain the present disclosure, and are not to be construed as limiting the disclosure.

In the description of the present disclosure, it is understood that features defining “first” and “second” may comprise one or more of the features, either explicitly or implicitly. In the description of the present disclosure, the phrase “a plurality of” means two or more unless otherwise stated.

In the description of the present disclosure, it should be noted that, unless otherwise explicitly specified and defined, the terms “install”, “connect”, and “contact” are to be understood broadly, and, for example, may be either a fixed contact or a detachable contact, or an one-piece contact; may be mechanical contact or electrical contact; and may be direct contact or indirect contact through an intermediate medium, which may be internal communication between two elements. For a person with ordinary skill in the art, the specific meanings of the above terms in the present disclosure can be understood according to a specific situation.

The inventors of the present disclosure have found that since the material and crystalline structures of the mask strip are different from those of the mask frame, it is relatively difficult to weld them and the effect of welding is not good.

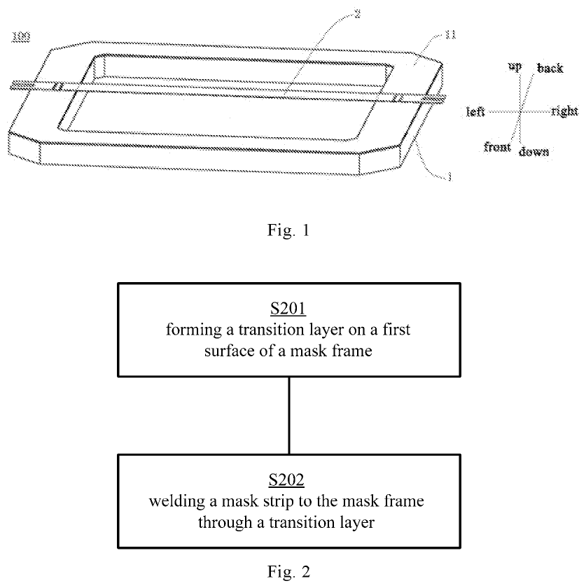

A mask plate 100 according to an embodiment of the present disclosure is described below with reference to FIG. 1. The mask plate 100 can be used for an evaporation device. In the evaporation process, the mask plate 100 may be disposed between a substrate to be evaporated and the evaporation device, and a pattern region on the mask plate 100 is aligned with a region to be evaporated of the substrate to transfer the pattern on the mask plate 100 to the substrate.

As shown in FIG. 1, the mask plate 100 according to one embodiment of the present disclosure comprises a mask frame 1 and a mask strip 2.

The mask frame 1 has a first surface and a second surface. The first surface and the second surface are oppositely disposed in the thickness direction of the mask frame 1. The first surface is provided with a transition layer 11. For example, in the example of FIG. 1, the mask frame 1 may be formed in a substantially rectangular frame structure, and each junction between two adjacent sides of the mask frame 1 are provided with a chamfering. The first surface and the second surface may be oppositely disposed in the up and down direction of FIG. 1. Specifically, in the orientation of FIG. 1, the first surface may be an upper surface of the mask frame 1, and the second surface may be a lower surface of the mask frame 1.

The mask strip 2 may be disposed on the mask frame 1 and connected to the transition layer 11, and the material of the transition layer 11 is the same as that of the mask strip 2. In this embodiment of the present disclosure, since the transition layer 11 is disposed on the mask frame 1 and the material of the transition layer 11 is the same as that of the mask strip 2, two objects of a same material can be easily welded together in a welding process, so that the mask strip 2 can be welded to the mask frame 1 conveniently and securely. This reduces the difficulty of welding, and improves the effect of welding, thereby improving the quality of the mask plate 100, and effectively avoiding influences of welding flaws on the service life of the mask plate 100.

It should be noted that although the mask strip 2 is schematically showed in FIG. 1 as extending along the length direction of the mask frame 1 (for example, the left-right direction in FIG. 1), as will be appreciated by the person with ordinary skill in the art, there may be a plurality of mask strips 2, each mask strip 2 may be provided with a pattern, patterns on the plurality of mask strips 2 may form a pattern region which corresponds to a pattern to be formed on the substrate. Therefore, the number and the specific pattern of the mask strips 2 can be adjusted and designed as needed, which is not specifically limited in the present disclosure.

In the description of the present disclosure, it is understood that, the orientation or positional relationship indicated by the terms “length”, “width”, “thickness”, “upper”, “lower”, “front”, “back”, “left”, “right”, etc. are based on the orientation or positional relationship shown in the accompanying drawings, and are merely for the ease of describing the present disclosure and the simplified description, without indicating or implying that the device or element indicated must have a particular orientation and is constructed and operated in a particular orientation, which is therefore not to be construed as limiting the disclosure.

In the mask plate 100 according to the embodiment of the present disclosure, since the transition layer 11 is disposed on the mask frame 1 and the material of the transition layer 11 is the same as that of the mask strip 2, two objects of a same material can be easily welded together in the welding process, so that the mask strip 2 can be welded to the mask frame 1 conveniently and securely. This reduces the difficulty of welding, and improves the effect of welding, thereby improving the quality of the mask plate 100, and effectively reducing influences of welding flaws on the service life of the mask plate 100.

According to some embodiments of the present disclosure, a crystalline structure of the transition layer 11 may be further the same as that of the mask strip 2. Thus, since the material and crystalline structure of the transition layer 11 are the same as those of the mask strip 2, the difficulty of welding can be further reduced, the effect of welding can be improved, and morphology of the solder junction can be improved. This further improves the quality of the mask plate 100 and makes the mask plate 100 more suitable for subsequent evaporation processes.

It should be noted that two objects of a same material do not necessarily mean that the two objects have a same crystalline structure. For example, carbon is a typical material which has a variety of crystalline structures. Depending on the different crystalline structures, carbon may be graphite, diamond, graphene or the like.

Optionally, in some specific embodiments of the present disclosure, the mask strip 2 may be an electroformed nickel piece, an electroformed cobalt piece, or an electroformed nickel iron piece, and the mask frame 1 may be an Invar piece. Correspondingly, since the material of the transition layer 11 is the same as that of the mask strip 2, the transition layer 11 is also an electroformed nickel piece, an electroformed cobalt piece, or an electroformed nickel iron piece.

Specifically, the transition layer 11 may be electroformed on the first surface of the mask frame 1. In this way, nickel, cobalt, nickel iron, or the like can be “grown” on the first surface of the mask frame 1 by electroforming. Namely, nickel, cobalt, and nickel iron are formed on the first surface of the mask frame 1 by a chemical reaction, so that a thin layer of a same material (in particular with a same crystalline structure) as the mask strip 2 is formed on the first surface. Thereafter, when the mask strip 2 is welded to the mask frame 1, two objects of a same material (in particular, and the same crystalline structure) are actually welded, so that a good contact can be achieved, the problem of welding difficulty due to different materials of the metals (such as nickel) and Invar alloy can be overcome. Besides, the electroforming process is simple and convenient, and does not affect the performance of the mask frame 1 itself.

It should be noted that the transition layer 11 according to an embodiment of the present disclosure may also be disposed on the first surface of the mask frame 1 a process other than electroforming. For example, the transition layer 11 may be disposed on the first surface of the mask frame 1 by a process such as evaporation, coating, or the like.

The material of the mask frame 1 is Invar alloy of a martensite crystalline structure, while the material of mask strip 2 is electroformed nickel, electroformed cobalt or electroformed nickel iron. The mask strip 2 is different from the mask frame 1 not only in term of material, but also the crystalline structure. It is extremely difficult to directly weld two objects having different materials and crystalline structures, and the effect of welding is not good. After electroforming the transition layer 11 having the same material and crystalline structure as the mask strip 2 on the mask frame 1, two objects of a same material and crystalline structure are actually welded, so that the difficulty of welding is low, and the welding quality is good. Besides, the electroforming process is simple and easy, and does not affect the performance of the mask frame 1 itself.

According to some specific embodiments of the present disclosure, the transition layer 11 is arranged across (throughout) the first surface of the mask frame 1. For example, the transition layer 11 can be electroformed across the first surface of the mask frame 1. Thereby, the electroforming process of the transition layer 11 can be conveniently simplified, and the mask strip 2 can be conveniently welded to the mask frame 1.

In other specific embodiments of the present disclosure, it is also possible that the transition layer 11 is only arranged on a portion of the first surface where the first surface is in contact with the mask strip 2. For example, the transition layer 11 may be electroformed only on a portion of the first surface where it is in contact with the mask strip 2. Thereby, it can also be convenient to weld the mask strip 2 to the mask frame 1, the material of the transition layer 11 can be saved, and the cost of material can be reduced.

Optionally, the mask strip 2 can be welded to the transition layer 11. For example, the mask strip 2 can be welded to the transition layer 11 by laser welding.

Other configurations and operations of the mask plate 100 according to embodiments of the present disclosure are known to the person with ordinary skill in the art and will not be described in detail herein.

In the mask plate 100 according to embodiments of the present disclosure, the mask strip 2 can be welded to the mask frame 1 conveniently and securely, thereby reducing the difficulty of welding, and improving welding strength of the mask strip 2 and morphology of the solder junction during welding. As a result, the resulting mask plate 100 is more suitable for subsequent evaporation.

The present disclosure also provides a method for fabricating the above mask plate 100. The mask plate 100 comprises a mask frame 1 and a mask strip 2. The mask frame 1 has a first surface and a second surface oppositely disposed in the thickness direction thereof, and the mask strip 2 is disposed on the first surface. As shown in FIG. 2, the method for fabricating the mask plate 100 comprises forming a transition layer 11 on the first surface at step S201, wherein the material of the transition layer 11 is the same as that of the mask strip 2; and welding the mask strip 2 to the mask frame 1 through the transition layer 11 at step S202.

For example, the transition layer 11 may be formed on the first surface by electroforming, and the mask strip 2 may be welded to the transition layer 11 by laser welding. Specifically, the transition layer 11 of a same material as the mask strip 2 may be electroformed across the first surface of the mask frame 1, or may also be electroformed only on a portion of the first surface where the first surface is in contact with the mask strip 2.

In some specific embodiments of the present disclosure, the mask strip 2 may be an electroformed nickel piece, an electroformed cobalt piece, or an electroformed nickel iron piece, and the mask frame 1 may be an Invar piece. Before welding, nickel, cobalt, nickel iron, or the like can firstly be “grown” on the first surface of the mask frame 1, e.g., by electroforming to form the transition layer 11. Namely, nickel, cobalt, and nickel iron are formed on the first surface of the mask frame 1 by a chemical reaction. In this way, a thin layer of a same material (in particular, with a same crystalline structure) as the mask strip 2 may be formed on the first surface. Thereafter, when the mask strip 2 is welded to the mask frame 1, two objects of a same material (in particular, with a same crystalline structure) are actually welded, so that a good contact effect can be achieved. The problem of welding difficulty due to different materials of the metals (such as nickel) and Invar alloy can be overcome. Therefore, the mask strip 2 can be welded to the mask frame 1 conveniently and securely. This reduces the difficulty of welding, and improves the effect of welding, thereby improving the quality of the mask plate 100, and effectively avoiding influences of welding flaws on the service life of the mask plate 100. Further, since the electroforming process is simple and convenient to process, it does not affect the performance of the mask frame 1 itself.

In the method for fabricating the mask plate 100 according to the embodiment of the present disclosure, since the transition layer 11 is disposed on the mask frame 1 and the material of the transition layer 11 is the same as that of the mask strip 2, the mask strip 2 can be welded to the mask frame 1 conveniently and securely. This reduces the difficulty of welding, and improves the effect of welding, and thereby improving the quality of the mask plate 100, and effectively avoiding influences of welding flaws on the service life of the mask plate 100.

Embodiments of the present disclosure also provide an evaporation device using any of the above-described mask plates 100.

In such an evaporation device, since the transition layer 11 is disposed on the mask frame 1 and the material of the transition layer 11 is the same as that of the mask strip 2, the mask strip 2 can be welded to the mask frame 1 conveniently and securely. This reduces the difficulty of welding, and improving the effect of welding, and thereby improves the quality of the mask plate 100, thus effectively avoiding influences of welding flaws on the service life of the mask plate 100. Therefore, the overall performance of the evaporation device is improved.

In the description of the present specification, the description with reference to the terms “one embodiment”, “some embodiments”, “exemplary embodiment”, “example”, “specific example”, or “some examples”, etc. means that particular features, structures, materials or characteristics described in conjunction with the embodiments or examples are comprised in at least one embodiment or example of the present disclosure. In the present specification, the schematic expression of the above terms does not necessarily refer to the same embodiment or example. Furthermore, the particular features, structures, materials, or characteristics described may be combined in a suitable manner in any one or more embodiments or examples. While the embodiments of the present disclosure have been shown and described, it will be understood by the person with ordinary skill in the art that the various changes, modifications, substitutions and variations of these embodiments may be made without departing from the principle and spirit of the disclosure. The scope of the disclosure is defined by the claims and their equivalent.

1. A mask plate, comprising:
a mask frame comprising a transition layer on a first surface of the mask frame; and
a mask strip,
wherein the mask strip is welded to the mask frame through the transition layer, and
wherein a material of the transition layer is a same material as that of the mask strip.

2. The mask plate according to claim 1, wherein a crystalline structure of the transition layer is a same crystalline structure as that of the mask strip.

3. The mask plate of claim 1, wherein a material of the mask strip is one of electroformed nickel, electroformed cobalt, or electroformed nickel iron, or a combination thereof.

4. The mask plate of claim 3, wherein the material of the transition layer is one of electroformed nickel, electroformed cobalt, or electroformed nickel iron, or a combination thereof.

5. The mask plate of claim 1, wherein the mask frame comprises an Invar piece.

6. The mask plate of claim 1, wherein the transition layer is arranged across the first surface of the mask frame.

7. The mask plate of claim 1,
wherein the transition layer is arranged on a portion of the first surface of the mask frame where the first surface of the mask frame is in contact with the mask strip.

8. The mask plate of claim 1, wherein the transition layer is electroformed on the first surface of the mask frame.

9. The mask plate of claim 1, wherein the mask strip is welded to the mask frame by laser welding.

10. A method for fabricating a mask plate comprising a mask frame and a mask strip, comprising:
forming a transition layer on a first surface of the mask frame, wherein a material of the transition layer is a same material as that of the mask strip; and
welding the mask strip to the mask frame through the transition layer.

11. The method according to claim 10, wherein a crystalline structure of the transition layer is a same crystalline structure as that of the mask strip.

12. The method according to claim 10, wherein the mask strip comprises one of nickel, cobalt, or nickel iron, or a combination thereof, by electroforming.

13. The method according to claim 12, wherein the transition layer comprises one of nickel, cobalt, or nickel iron, or a combination thereof, by electroforming.

14. The method according to claim 10, wherein the mask frame comprises an Invar piece.

15. The method according to claim 10, wherein the forming the transition layer on the first surface of the mask frame comprises:
forming the transition layer across the first surface of the mask frame.

16. The method according to claim 10, wherein the forming the transition layer on the first surface of the mask frame comprises:
forming the transition layer on a portion of the first surface of the mask frame where the first surface is in contact with the mask strip.

17. The method according to claim 10, wherein the forming the transition layer on the first surface of the mask frame comprises:
forming the transition layer on the first surface of the mask frame by electro forming.

18. The method according to claim 10, wherein the welding the mask strip to the mask frame through the transition layer comprises:
welding the mask strip to the mask frame through the transition layer by laser welding.

19. An evaporation device using the mask plate according claim 1.
